(19) United States
(12) Patent Application Publication
(10) Pub. No.: US 2017/0117144 A1
(43) Pub. Date: Apr. 27, 2017

(54) Chemical Infiltration into Porous Dielectric Films

(71) Applicant: Applied Materials, Inc., Santa Clara, CA (US)

(72) Inventors: Lakmal Kalutarage, San Jose, CA (US); Mark Saly, Santa Clara, CA (US); David Thompson, San Jose, CA (US)

(21) Appl. No.: 15/299,708

(22) Filed: Oct. 21, 2016

Related U.S. Application Data
(60) Provisional application No. 62/244,818, filed on Oct. 22, 2015.

(51) Int. Cl. H01L 21/02

(52) U.S. Cl. CPC H01L 21/02321; H01L 21/02203; H01L 21/0234

(57) ABSTRACT

Methods for modifying the properties of a porous film are described. An infiltrating material is deposited within the pores of the porous film.

### CROSS-REFERENCE TO RELATED APPLICATIONS

This application claims priority to U.S. Provisional Application No. 62/244,818, filed Oct. 22, 2015, the entire disclosure of which is hereby incorporated by reference herein.

### TECHNICAL FIELD

The present disclosure relates generally to methods of depositing thin films. In particular, the disclosure relates to processes to improve qualities of dielectric films.

### BACKGROUND

Integrated circuits have evolved into complex devices that can include millions of components (e.g., transistors, capacitors and resistors) on a single chip. The evolution of chip designs continually requires faster circuitry and greater circuit densities. The demand for greater circuit densities necessitates a reduction in the dimensions of the integrated circuit components.

As the dimensions of the integrated circuit components are reduced (e.g., sub-micron dimensions), the materials used to fabricate such components contribute to the electrical performance of such components. For example, poor dielectric film quality may result in shrinkage or break-down. Many dielectric films are porous in nature and may suffer from high etch rates, high shrinkage and/or low heat tolerance. Therefore, there is a need in the art for methods of depositing or treating porous dielectric materials to improve film quality.

### SUMMARY

One or more embodiments of the disclosure are directed to processing methods comprising exposing a substrate surface having a porous film thereon to a precursor and reactant to form an infiltrating material to at least partially fill pores in the porous film.

Additional embodiments of the disclosure are directed to processing methods comprising positioning a substrate surface in a processing chamber. The substrate surface has a porous dielectric film thereon. The substrate surface is sequentially exposed to a precursor and a reactant to deposit an infiltrating material into the pores, the infiltrating material comprising one or more of Si, Al or Ti.

Further embodiments of the disclosure are directed to processing methods comprising placing a substrate having a substrate surface into a processing chamber comprising a plurality of sections. Each section is separated from adjacent sections by a gas curtain. The substrate surface has a porous dielectric comprising one or more of flowable SiO₂, SiN, SiCN, SiCON, SiBN, SiCBN or SiC deposited thereon. At least a portion of the substrate surface is exposed to a first process condition in a first section of the processing chamber. The first process condition comprises a precursor having the formula (I), (II), (Ill), (IV), (V) or (VI)

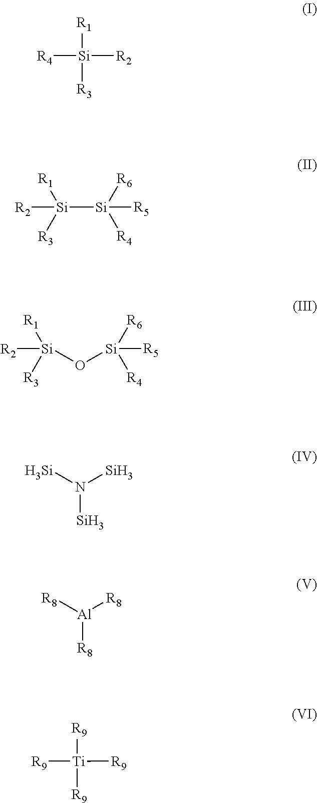

where each R₁-R₆ is independently H, alkyl, vinyl, acetalide, O-alkyl, O-vinyl, Cl, Br, I, N(alkyl)₂, NH(alkyl),

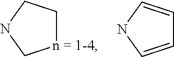

where each R₈ is independently an alkyl group, each R₉ is independently Cl, N(alkyl)₂, OCH(CH₃)₂, N(CH₃)(C₂H₅) or OCH₃(C₅Me₅). The substrate surface is laterally moved through a gas curtain to a second section of the processing chamber. The substrate surface is exposed to a second process condition in the second section of the processing chamber. The second process condition comprises a reactant comprising one or more of O₂, O₃, NH₃, N₂O, N₂ or a plasma of O₂, NH₃, N₂O or N₂. The substrate surface is laterally moved through a gas curtain. Exposure to the first process condition and the second process condition including lateral movement of the substrate surface is repeated for a total number of cycles less than or equal to about 50.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the disclosure are directed to methods to improve film quality by infiltrating materials to porous dielectric films. The infiltration materials include, but are not limited to, SiO₂, SiN, SiCN, SiCON, SiC, metal oxides (e.g., Al₂O₃, Ti₂O₃) and combinations thereof. In some embodiments, a Si-, Al-, or Ti-containing precursor and a common co-reactant such as O₂, O₃, or NH₃ can be used to deposit materials in the pores of porous dielectric thin films.

The porous nature of the ALD/CVD SiO₂, SiN, SiCN, SiCON, SiC thin films can result in low density films. Also, flowable SiO₂, SiN, SiCN, SiCON, SiC thin films have some porosity and less network. Moreover, porous dielectric films may have high etch rates, high shrinkage, and/or are unable to withstand high temperatures. The inventors have found that infiltrating new molecules inside the pores and depositing new layers may reduce wet etch rates and/or shrinkage. However, currently there is no infiltration process designed to increase the density as well as decrease the etch rate and shrinkage of Si-containing thin films.

Embodiments of the disclosure are directed to methods to decrease etch rate and shrinkage by infiltrating porous ALD/CVD dielectric films. Porosity in dielectric thin films is believed to be due to mismatching of Si precursor to co-reactant ratio, large size of precursor molecules that inhibit uniform growth of thin films, insufficient reaction times and/or insufficient flowability in flowable films. The presence of pores within films leads to low density films.

The pores tend to have reactive surfaces including —OH, —NH, and —NH₂. The reactive species tend to react with one another leading to film reorganization in turn resulting in film shrinkage upon exposure to high temperature processes (high temperature may be used to increase the density or films may feel high temperatures during a later stage of the integration). Shrinkage of films could lead to collapse of the entire film stack and removal of the film from the substrate surface. In addition, the presence of pores in a thin film increases etching, enabling the etchant to readily penetrate the film. Furthermore, porous films are likely to allow penetration of a new incoming precursor that is expected to deposit a new layer on top of the current dielectric film. This enabling of penetration of new precursors possibly leads to the formation of undesired layers of material within the film.

The infiltration process of various embodiments can be performed immediately after the dielectric film deposition is completed (without air break) or at a later time (with air break). When using halogenated Si precursors to deposit the original film, infiltration may be more useful after an air break. Without being bound by theory, it is believed that performing infiltration after air exposure increases the chances of reaction between the infiltrating precursor and the surface of pores because unreactive halogenated surfaces are converted to reactive —OH surfaces upon exposure to air.

One or more embodiments of the disclosure provide films with enhanced properties. Some embodiments of the disclosure provide films with higher density than prior to infiltration. Some embodiments of the disclosure provide films with lower wet etch rate ratios (WERR) than prior to infiltration.

Infiltration can be achieved by ALD or CVD methods. In some embodiments, infiltration is performed by an ALD process which can yield controlled deposition of good quality thin films in very small areas. Also, ALD is expected to minimize the deposition of the film on top of the pre-deposited film.

Depending on the material of the thin film (SiO₂, SiN, SiCN, SiCON, SiBN, SiCBN or SiC) that is to be infiltrated, a Si precursor and a co-reactant can be chosen. In some embodiments, the porous film comprises one or more of SiO₂, SiN, SiCN, SiCON, SiBN, SiCBN or SiC.

In some embodiments, Si precursors comprise one or more compounds having structures according to (I), (II), (Ill) or (IV) together with a suitable coreactant (e.g., O₂, O₃, NH₃, N₂ or plasma enhanced O₂, NH₃, or N₂).

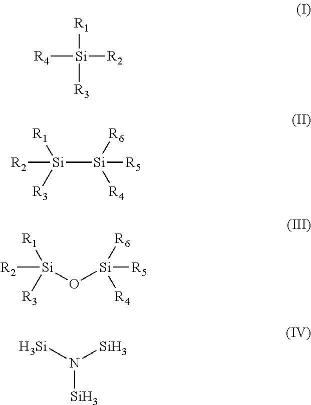

where each R₁-R₆ is independently H, alkyl, vinyl, acetalide, O-alkyl, O-vinyl, Cl, Br, I, N(alkyl)₂, NH(alkyl),

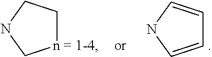

For example, when n=1, there five atoms in the ring and when n=4 there are eight atoms in the ring.

In some embodiments, metal oxides including Al₂O₃ and Ti₂O₃ are infiltrated into dielectric films. Suitable Al or Ti precursors include, but are not limited to, structures (V) and (VI).

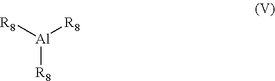

where each R₈ is independently an alkyl group. In some embodiments, each of the R₈ groups are the same. In some embodiments, at least one of the R₈ groups are different from the other R₈ groups. Suitable alkyl groups for R₈ include, but are not limited to methyl, ethyl, propyl, butyl or combinations thereof.

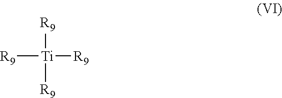

where each R₉ is independently Cl, N(alkyl)₂, OCH(CH₃)₂, N(CH₃)(C₂H₅) or OCH₃(C₅Me₅).

The Al or Ti precursor can be reacted with, for example, water, O₂, O₂ plasma, O₃, N₂O or combinations thereof as the co-reactant.

In some embodiments, the Si/Al/Ti precursor is selected to match the pore size of the film in which the precursor will infiltrate. For example, if a precursor that is lager in size than the size of the pores is used to infiltrate a film it is likely that infiltration might not occur.

Infiltration can be accomplished using either Chemical Vapor Deposition (CVD) or Atomic Layer Deposition (ALD). In a CVD type process, the precursor (e.g., Si, Ti or Al compound) and the reactant (e.g., O₂) are mixed in the gas phase to react and deposit onto the substrate. In an ALD process, the precursor and reactant are prevented from reacting in the gas phase so that each contacts the substrate separately.

According to one or more embodiments, the method uses an atomic layer deposition (ALD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap. As used in this specification and the appended claims, the terms “precursor”, “reactant”, “reactive gas” and the like are used interchangeably to refer to any gaseous species that can react with the substrate surface.

An ALD process is a self-limiting process where a single layer of material is deposited using a binary (or higher order) reaction. An individual reaction in the ALD process continues until all available active sites on the substrate surface have been reacted. ALD processes can be performed by time-domain or spatial ALD.

In a time-domain process, the processing chamber and substrate are exposed to a single reactive gas at any given time. In an exemplary time-domain process, the processing chamber might be filled with a metal precursor for a time to allow the metal precursor to fully react with the available sites on the substrate. The processing chamber can then be purged of the precursor before flowing a second reactive gas into the processing chamber and allowing the second reactive gas to fully react with the active sites on the substrate. The time-domain process minimizes the mixing of reactive gases by ensuring that only one reactive gas is present in the processing chamber at any given time. At the beginning of any reactive gas step, there is a delay in which the concentration of the reactive species must go from zero to the final predetermined pressure. Similarly, there is a delay in purging all of the reactive species from the process chamber.

In a spatial ALD process, the substrate is moved between different process regions within a single processing chamber. Each of the individual process regions is separated from adjacent process regions by a gas curtain. The gas curtain helps prevent mixing of the reactive gases to minimize any gas phase reactions.

According to some embodiments, a substrate having a pre-deposited porous film is positioned in a processing chamber. A Si, Al or Ti precursor with the general formula (I) through (VI) is vaporized and flowed into the processing chamber containing the substrate with the porous film. The precursor molecules can react with the surface of pores through, for example, chemisorption. In some embodiments, a soak time is given so that the precursor molecules can penetrate into the film to react with pore surfaces. The soak time can vary depending on, for example, the size of the precursor, the concentration of the precursor, the reactivity of the precursor and process temperature.

After allowing the precursor to react with the pores, an inert purge gas is applied to remove unreacted precursor molecules. These unreacted molecules can be within the pores or adjacent the surface of the substrate.

After purging, the coreactant (e.g., O₂, O₃, NH₃, N₂) is vaporized and flowed into the processing chamber to react with chemisorb precursor molecules to form the infiltration material (e.g., SiO₂, SiN, SiCN, SiCON, SiC). In some embodiments, a plasma enhanced species of the co-reactant could be used to enhance reactivity.

The substrate is subjected to an inert gas purge to remove unreacted species and by-product molecules.

In some embodiments, the cycle of precursor/purge/reactant/purge is repeated to deposit the infiltration material within pores. The deposition cycle can be repeated any suitable number of times to deposit material within the pores. In some embodiments, the deposition cycle is repeated less than about 50 times, 40 times, 30 times, 25 times or 20 times.

In some embodiments, the infiltration material is deposited substantially only within the pores of the film. As used in this regard, the term “substantially only within the pores” means that greater than or equal to about 50% w/w of the deposited material is within the pores. In some embodiments, greater than or equal to about 60%, 70%, 80%, 90% or 95% of the deposited material is deposited within the pores.

In some embodiments, the infiltration material is deposited on top of the porous film giving increased thickness. In one or more embodiments, the infiltration material is deposited within the pores and on top of the porous film.

The substrate temperature can be any suitable temperature depending on, for example, the precursors, the reactants, the thermal budget of the device being formed. In some embodiments, the temperature is maintained within the range of about 50° C. to about 400° C., or in the range of about 100° C. to about 350° C.

One or more embodiments of the disclosure are directed to methods of infiltration using CVD. In CVD-based methods, the Si/Al/Ti precursor (selected from Structures (I) through (VI)) and co-reactant may be flowed simultaneously into the process chamber containing a pre-deposited ALD/CVD porous film to enable formation of the new material inside the pores. The film can be deposited inside the pores and/or on the surface.

The infiltration method of some embodiments generates a high density dielectric film with low etch rates and low shrinkage. Additionally, the infiltration can be carried out quickly because only a few layers of the materials might be used to fill the pores. Conventionally, high temperature annealing or high temperature gas annealing is performed to convert low density films to high density films, which use additional tools and resources. The infiltration can be carried out in a conventional deposition chamber. If annealing is still used, the annealing temperature could be lower than would otherwise be used.

### Example 1

Infiltration of ALD SiO₂ was studied on flowable porous films. An as-deposited flowable SiO₂ film (obtained from octamethylcyclotetrasiloxane and O₂ RPS) was infiltrated by ALD SiO₂ using BDEAS (Structure VII) as the Si precursor and O₃ as the co-reactant.

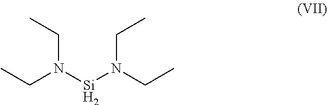

Pores in the film were verified by SEM. Twenty ALD cycles of BDEAS/O₃ at 150° C. were carried out on this film and one ALD cycle of BDEAS (1 s) pulse/soak, throttle valve closed (3 s), [purge (10 s)/pump (20 s)]×2, O₃ (1 s) pulse/soak−throttle valve closed (10 s), and [purge (10 s)/pump (20 s)]×2. SEM obtained after the infiltration shows that the pore sizes were reduced as a result of the ALD SiO₂ deposition inside the pores.

### Example 2

As-deposited flowable films were infiltrated with ALD of TiO₂ and Al₂O₃. TiCl₄ and TMA (trimethylaluminum) were used as the metal precursors and H₂O was used as the co-reactant. Thirty ALD cycles were employed and one ALD cycle of TiCl₄ or TMA (2 s) pulse/soak−throttle valve closed (30 s), [purge (10 s)/pump (20 s)]×2, H₂O (3 s) pulse/soak−throttle valve closed (30 s), and [purge (10 s)/pump (20 s)]×2. Soak times were applied to give sufficient time for infiltration and reactions, and long pump/purge were given to remove unreacted precursors and byproducts. TiO₂ and Al₂O₃ were infiltrated at the temperatures of 200 and 130° C., respectively.

Two films were thermally annealed at 200 and 130° C. without ALD cycles to measure the impact of thermal annealing on film quality.

One film was prepared using the same pulsing recipe as above with no TiCl₄ or TMA pulses to partition the impact of a low temperature H₂O anneal on film quality.

The wet etch rate (WER) of the films were measured in dilute HF (1:100) after the infiltration and are summarized in Table 1. The as-deposited film had a WER over 900 Å/min and thermal annealing brought the WER down to 340 and 497 Å/min at 200° C. and 130° C. annealing, respectively. TiO₂ and Al₂O₃ infiltrated films had WERs of 72 and 146 Å/min, respectively.

TABLE 1

| Sample | WER (Å/min) |
|---|---|
| As deposited | 990 |
| TiO₂ @ 200° C. | 72 |
| 200° C. | 340 |
| Al₂O₃ @ 130° C. | 146 |
| 130° C. | 497 |

The WER depth profile of TiO₂ and Al₂O₃ infiltrated and H₂O treated films was evaluated. The water treated film had a very low WER initially because the top layers of the film are crusted with H₂O annealing. However, the WER of the bulk of the film was higher than that of Al₂O₃ and TiO₂ infiltrated films suggesting an impact on WER after infiltrations.

Infiltrations were performed on patterned coupons and TEM/EELS were taken. According to the composition analyses, Ti and Al penetrated about 300 Å. There was about 10 Å TiO, film on the Ti infiltrated film and about 150 Å Al₂O, film on Al infiltrated film. Metal infiltration to flowable films was demonstrated and the precursors used for infiltration were observed to form layers on top of the films resulting in blocking of further infiltration.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A processing method comprising exposing a substrate surface having a porous film thereon to a precursor and reactant to form an infiltrating material to at least partially fill pores in the porous film.

2. The method of claim 1, wherein exposing the porous film to the infiltrating material comprises sequentially exposing the substrate surface to the precursor and the reactant.

3. The method of claim 1, wherein exposing the porous film to the infiltrating material comprises flowing the precursor and the reactant into a processing chamber at the same time to mix in gas phase.

4. The method of claim 1, wherein the porous film comprises a dielectric.

5. The method of claim 4, wherein the porous film comprising one or more of flowable SiO₂, SiN, SiCN, SiCON or SiC.

6. The method of claim 1, wherein the infiltrating material comprises Si.

7. The method of claim 6, wherein the precursor comprise one or more compounds having structures according to (I), (II), (Ill) or (IV) 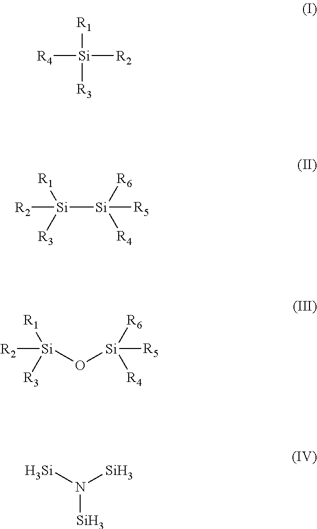
where each R₁-R₆ is independently H, alkyl, vinyl, acetalide, O-alkyl, O-vinyl, Cl, Br, I, N(alkyl)₂, NH(alkyl),

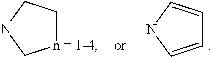

8. The method of claim 7, wherein the reactant comprises one or more of O₂, O₃, NH₃, N₂ or a plasma of O₂, NH₃, N₂O or N₂.

9. The method of claim 1, wherein the infiltrating material comprises Al.

10. The method of claim 9, wherein the precursor comprises a compound having a formula (V): 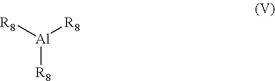
where each R₈ is independently an alkyl group.

11. The method of claim 10, wherein the reactant comprises one or more of water, O₂, O₂ plasma or O₃.

12. The method of claim 1, wherein the infiltrating material comprises Ti.

13. The method of claim 12, wherein the precursor comprises a compound having a formula (VI): 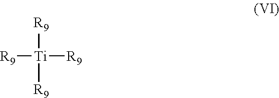
where each R₉ is independently Cl, N(alkyl)₂, OCH(CH₃)₂, N(CH₃)(C₂H₅) or OCH₃(C₅Me₅).

14. The method of claim 13, wherein the reactant comprises one or more of water, O₂, O₂ plasma or O₃.

15. A processing method comprising:
positioning a substrate surface in a processing chamber, the substrate surface having a porous dielectric film thereon; and
sequentially exposing the substrate surface to a precursor and a reactant to deposit an infiltrating material into the pores, the infiltrating material comprising one or more of Si, Al or Ti.

16. The processing method of claim 15, wherein the precursor comprises one or more compounds having structures according to (I) through (VI) 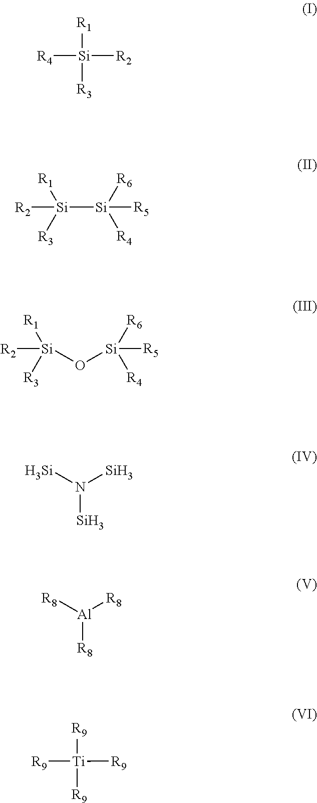
where each R₁-R₆ is independently H, alkyl, vinyl, acetalide, O-alkyl, O-vinyl, Cl, Br, I, N(alkyl)₂, NH(alkyl), 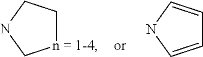
where each R₈ is independently an alkyl group, each R₉ is independently Cl, N(alkyl)₂, OCH(CH₃)₂, N(CH₃)(C₂H₅) or OCH₃(C₅Me₅).

17. The method of claim 16, wherein the precursor comprises a structure of (I), (II), (Ill) or (IV) and the reactant comprises one or more of O₂, O₃, NH₃, N₂ or a plasma of O₂, NH₃, N₂O or N₂.

18. The method of claim 16, wherein the precursor comprises a structure of (V) or (VI) and the reactant comprises one or more of water, O₂, O₂ plasma or O₃.

19. The method of claim 15, wherein the porous dielectric film comprising one or more of flowable SiO₂, SiN, SiCN, SiCON SiBN, SiCBN or SiC.

20. A processing method comprising:
placing a substrate having a substrate surface into a processing chamber comprising a plurality of sections, each section separated from adjacent sections by a gas curtain, the substrate surface having a porous dielectric comprising one or more of flowable SiO₂, SiN, SiCN, SiCON, SiBN, SiCBN or SiC deposited thereon;
exposing at least a portion of the substrate surface to a first process condition in a first section of the processing chamber, the first process condition comprising a precursor having the formula (I), (II), (Ill), (IV), (V) or (VI) 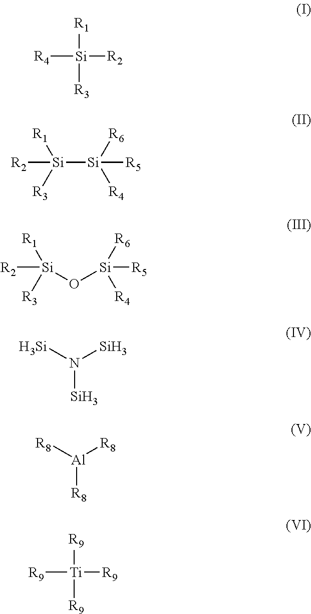
where each R₁-R₆ is independently H, alkyl, vinyl, acetalide, O-alkyl, O-vinyl, Cl, Br, I, N(alkyl)₂, NH(alkyl), 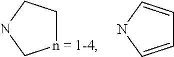
where each R₈ is independently an alkyl group, each R₉ is independently Cl, N(alkyl)₂, OCH(CH₃)₂, N(CH₃)(C₂H₅) or OCH₃(C₅Me₅);
laterally moving the substrate surface through a gas curtain to a second section of the processing chamber;
exposing the substrate surface to a second process condition in the second section of the processing chamber, the second process condition comprising a reactant comprising one or more of O₂, O₃, NH₃, N₂O, N₂ or a plasma of O₂, NH₃, N₂O or N₂;
laterally moving the substrate surface through a gas curtain; and
repeating exposure to the first process condition and the second process condition including lateral movement of the substrate surface for a total number of cycles less than or equal to about 50.
